(19) United States
(12) Patent Application Publication
(10) Pub. No.: US 2026/0160799 A1
(43) Pub. Date: Jun. 11, 2026

(54) PREDICTION METHOD AND DEVICE

(71) Applicant: Nuvoton Technology Corporation, Hsinchu Science Park (TW)

(72) Inventor: Chien-Che HUNG, Jhudong Township (TW)

(21) Appl. No.: 19/398,922

(22) Filed: Nov. 24, 2025

(30) Foreign Application Priority Data
Dec. 10, 2024 (TW) 113147766

(51) Int. Cl. G01R 31/28; G06N 20/00

(52) U.S. Cl. CPC G01R 31/2831; G06N 20/00

(57) ABSTRACT

A prediction method for predicting the yield of a batch of wafers is provided. During a training period, a plurality of wafer acceptance test (WAT) sample data of a plurality of first wafers are received, a wafer probe (CP) test is performed on the first wafers to generate a plurality of CP sample data, and the WAT sample data and the CP sample data are input into a machine learning model. The machine learning model calculates the WAT sample data and the CP sample data to generate a correlation. During a prediction period, WAT measurement data is input into a trained machine learning model. The trained machine learning model predicts the yield of the batch of wafers according to the correlation and the WAT measurement data.

### CROSS REFERENCE TO RELATED APPLICATIONS

This Application claims priority of Taiwan Patent Application No. 113147766, filed on Dec. 10, 2024, the entirety of which is incorporated by reference herein.

### TECHNICAL FIELD

The present disclosure relates to a prediction method, and, in particular, it relates to a prediction method for predicting wafer yield.

### BACKGROUND

Upon completion of wafer fabrication, the foundry delivers the entire batch of wafers to the tester. The tester performs a test operation on all the dies on each wafer to determine the yield of the wafer. However, the test operation includes numerous test items, and testing each die individually requires significant time and manpower.

### BRIEF SUMMARY

An embodiment of the present disclosure provides a prediction method for predicting the yield of a batch of wafers. An exemplary embodiment of the prediction method is described in the following paragraph. During a training period, a plurality of wafer acceptance test (WAT) sample data of a plurality of first wafers are received. During the training period, a wafer probe (CP) test is performed on the first wafers to generate a plurality of CP sample data. During the training period, the WAT sample data and the CP sample data are input into a machine learning model. The machine learning model calculates the WAT sample data and the CP sample data to generate a correlation. During a prediction period, WAT measurement data is input into a trained machine learning model. The trained machine learning model predicts the yield of the batch of wafers according to the correlation and the WAT measurement data.

An embodiment of the present disclosure provides a prediction device for predicting the yield of a batch of wafers. The prediction device comprises a storage circuit, an input-output interface, and a processing circuit. The storage circuit stores a machine learning model. The input-output interface is configured to receive a plurality of WAT sample data and a plurality of CP sample data. The processing circuit accesses the storage circuit to read the machine learning model. During the training period, the processing circuit provides the WAT sample data and the CP sample data to the machine learning model. The first machine learning model calculates the WAT sample data and the CP sample data to generate a correlation. During a prediction period, the input-output interface receives WAT measurement data, and the processing circuit inputs the WAT measurement data into a trained machine learning model. The trained machine learning model predicts the yield of the batch of wafers according to the correlation and the WAT measurement data.

An embodiment of the present disclosure provides a computer readable media storing a program code. In response to the program code being executed, the program code accomplishes steps which comprises a plurality of WAT sample data of a plurality of wafers are received during a training period. During the training period, a CP test is performed for the wafers to generate a plurality of CP sample data. During the training period, the WAT sample data and the CP sample data are input into a machine learning model. The machine learning model calculates the plurality of WAT sample data and the plurality of CP sample data to generate a correlation. During a prediction period, WAT measurement data is input into the machine learning model. The machine learning model predicts the yield of the batch of wafers according to the correlation and the WAT measurement data.

Prediction methods may be practiced by the systems which have hardware or firmware capable of performing particular functions and may take the form of program code embodied in a tangible media. When the program code is loaded into and executed by an electronic device, a processor, a computer or a machine, the electronic device, the processor, the computer or the machine becomes a prediction device for practicing the disclosed method.

### BRIEF DESCRIPTION OF THE DRAWINGS

The present disclosure can be more fully understood by reading the subsequent detailed description and examples with references made to the accompanying drawings, wherein:

FIG. 1 is a flowchart of an exemplary embodiment of a prediction method according to various aspects of the present disclosure; and

FIG. 2 is a schematic diagram of an exemplary embodiment of a prediction device according to various aspects of the present disclosure.

### DETAILED DESCRIPTION

The present disclosure will be described with respect to particular embodiments and with reference to certain drawings, but the disclosure is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the present disclosure.

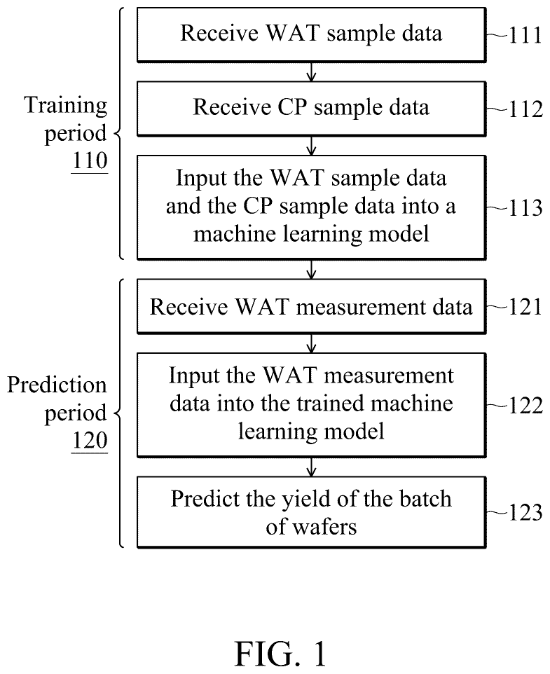

FIG. 1 is a flowchart of an exemplary embodiment of a prediction method according to various aspects of the present disclosure. The prediction method predicts the yield of a batch of wafers. The batch of wafers has a plurality of wafers. For example, each batch of wafers may have 25 wafers, and each wafer has a plurality of dies. The prediction method of the present invention can predict the yield of each die of each wafer. The prediction method of the present disclosure can be implemented through program code. The program code may be stored in a computer readable media. When the program code in the computer readable media is loaded and executed by a machine, the machine becomes a prediction device for practicing the disclosed method.

During a training period 110, a plurality of wafer acceptance test (WAT) data are received (step 111). In one embodiment, the WAT data is provided by a wafer foundry. The wafer foundry performs a test on each batch of wafers to generate the WAT data.

For example, assume that each batch of wafers has 25 wafers, each wafer has 6 test points, and the wafer foundry performs 100 test items on each test point. In this case, each WAT data records the test results of 25 wafers. In other words, each WAT data has 25*6*100 test results. In this embodiment, the WAT data in step 111 is the test results of multiple batches of wafers. For brevity, the WAT data during the training period 110 is called WAT sample data.

In some embodiments, the manufacturing specifications of each batch of wafers may be different. For example, the first batch of wafers may come from a first process route, which may be used to produce 55 nm (nanometer) wafers, and the second batch of wafers may come from a second process route, which may be used to produce 65 nm wafers. In this case, each WAT data records the process route data of the batch of wafers.

During the training period 110, a chip probing (CP) test is performed on the plurality of wafers recorded in the WAT sample data to generate a plurality of CP sample data (step 112). In one embodiment, if the first WAT sample data is the test results of a first batch of wafers, then step 112 performs the CP test on each wafer in the first batch of wafers. Since the first batch of wafers comprises a plurality of wafers, after the CP test is completed, step 112 generates a plurality of CP sample data.

In one embodiment, the CP test is to perform multiple electrical tests on each die of each wafer. Assume that the CP test includes 100 test items, each wafer has 1000 dies, and each batch of wafers has 25 wafers. After the CP test, a record file (data-log) can be generated. Each record file includes the electrical test results of each wafer in each batch of wafers. For example, each record file may include 100*1000*25 electrical test results. In this case, each record file serves as CP sample data.

During the training period 110, the WAT sample data and the CP sample data are input into a machine learning model (step 113). In one embodiment, the machine learning model calculates the WAT sample data and the CP sample data to generate a correlation. For example, the correlation may include the correlation between a specific parameter (such as Rs_P2) in the WAT sample data and a test item (such as RC22M) in the CP sample data. When the specific parameter (such as Rs_P2) is larger, the test item (such as RC22M) is more likely to fail, such as the test result is not within a normal range.

In some embodiments, the machine learning model generates a correlation according to the WAT sample data and the abnormal electrical test results of the CP sample data. For example, assume that the test result of a specific test item (such as RC22M) of the CP sample data is an abnormal result. In this case, the machine learning model determines which test result of the WAT sample data is correlated with the abnormal result of the specific test item. Assume that there is a correlation between a specific parameter (such as Rs_P2) of the WAT sample data and the abnormal result of the specific test item in the CP sample data. In this case, the machine learning model establishes a correlation between the specific parameter (such as Rs_P2) of the WAT sample data and the specific test item (such as RC22M) of the CP sample data.

Next, during a prediction period 120, the WAT data is received (step 121). In one embodiment, a wafer foundry not only provides a batch of wafers but provides the WAT data for the batch of wafers. For brevity, the WAT data during the prediction period 120 is referred to as the WAT measurement data. In one embodiment, the WAT measurement data and the WAT sample data are provided by the same wafer foundry.

The WAT measurement data is input into the trained machine learning model (step 122). In some embodiments, assumed that step 113 trains a corresponding machine learning model according to the process route data recorded in the WAT sample data during the training period 110. When the process route data recorded in the first WAT sample data is related to a 55 nm process, step 113 inputs the first WAT sample data and the corresponding first CP sample data into a first machine learning model. When the process route data recorded in the second WAT sample data is related to a 65 nm process, step 113 inputs the second WAT sample data and the corresponding second CP sample data into a second machine learning model. When the process route data recorded in the third WAT sample data is related to a 55 nm process, step 113 inputs the third WAT sample data and the corresponding third CP sample data into the first machine learning model. In this case, step 113 is performed to train the first and second machine learning models. Therefore, during the prediction period 120, step 122 selects a corresponding machine learning model according to the process route data recorded in the WAT measurement data. For example, when the process route data recorded in the WAT measurement data is related to a 55 nm process, step 122 selects the first machine learning model and inputs the WAT measurement data into the first machine learning model.

Next, the machine learning model is used to calculate the correlation and the WAT measurement data to predict the yield of the batch of wafers corresponding to the WAT measurement data (step 123). Since the correlation represents the correlation and strength between the test items of the WAT sample data and the test items of the CP sample data, the yield of the wafer can be predicted according to the correlation.

For example, assume that the correlation indicates that when a specific parameter (such as Rs_P2) of the WAT sample data exceeds a threshold value, the corresponding wafer cannot pass a specific test item (such as RC22M) in the CP test. In this case, when the machine learning model determines that a specific parameter (such as Rs_P2) of the WAT measurement data exceeds a threshold value, step 123 is performed to directly mark the specific test item of the corresponding wafer as failed. Since there is no need to perform the CP test on each wafer, the test time and test manpower can be greatly reduced.

In other embodiments, step 123 is performed to further predict the location of defective dies. For example, after performing the CP test, the CP sample data and a CP map are generated. The CP map shows the location of defective dies. Therefore, during the training period 110, if the CP map is input into the machine learning model, the correlation generated by the machine learning model also includes location information. During the prediction period 120, step 123 not only predicts the yield of each wafer in the batch of wafers, but also predicts the location of the defective dies on each wafer.

In some embodiments, the CP test includes a plurality of test items, the first part of the test items corresponds to a first product, and the second part of the test items corresponds to a second product. The types of the first and second products are not limited in the present disclosure. In one embodiment, the first and second products are functional circuits for providing predetermined functions. Taking the first product as an example, the first product may be a conversion circuit (such as an ADC or DAC) that provides a conversion function. In another embodiment, the first product is a control circuit (such as a DMA controller) that provides a control function. In some embodiments, step 123 is performed to further predict the yield of the first and second products in a batch of wafers.

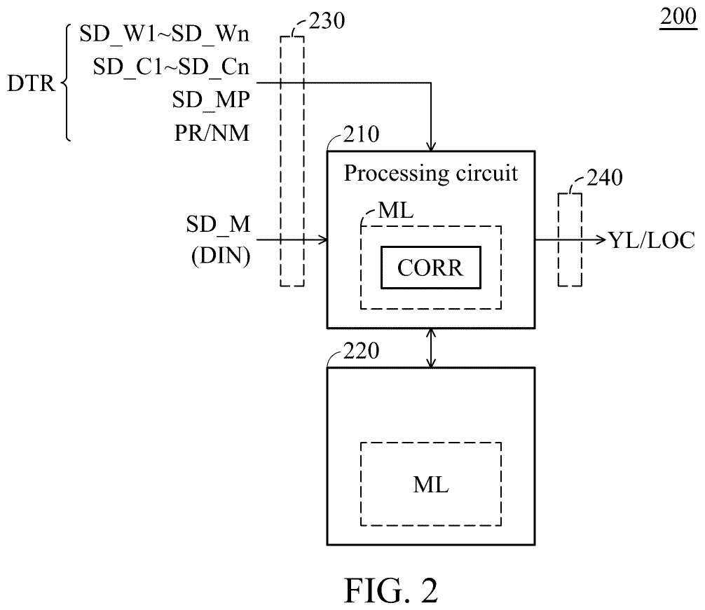

FIG. 2 is a schematic diagram of an exemplary embodiment of a prediction device according to various aspects of the present disclosure. The prediction device 200 is used to predict the yield of a batch of wafers and comprises a processing circuit 210 and a storage circuit 220. The storage circuit 220 stores a machine learning model ML. In one embodiment, the storage circuit 220 comprises a non-volatile memory for storing the machine learning model ML.

The processing circuit 210 accesses the storage circuit 220 to read the machine learning model ML. In this embodiment, the processing circuit 210 uses the training data DTR to train the machine learning model ML. The training data DTR includes a plurality of WAT sample data SD_W1˜SD_Wn and a plurality of CP sample data SD_C1˜SD_Cn. During a training period, the processing circuit 210 loads the machine learning model ML and inputs the WAT sample data SD_W1˜SD_Wn and the plurality of CP sample data SD_C1˜SD_Cn into the machine learning model ML to train the machine learning model ML. The machine learning model ML calculates the WAT sample data SD_W1˜SD_Wn and the CP sample data SD_C1˜SD_Cn to generate a correlation CORR. In one embodiment, the processing circuit 210 writes the trained machine learning model ML and the correlation CORR into the storage circuit 220.

In other embodiments, the training data DTR further comprises process route data PR. The processing circuit 210 selects different machine learning models according to different process route data PR. In this case, the storage circuit 220 stores multiple machine learning models which predict the yields of wafers which have different process route data PR. In some embodiments, the process route data PR is recorded in the WAT sample data SD_W1˜SD_Wn.

In one embodiment, the training data DTR further includes product data NM, such as a IP name. The product data NM may be recorded in the CP sample data SD_C1˜SD_Cn. In this case, the CP sample data SD_C1˜SD_Cn are multiple electrical test results of different batches of wafers. A part of the electrical tests in the electrical test results are for a first product (such as an ADC circuit), and another part of the electrical tests in the electrical test results are for a second product (such as a DAC circuit). In this case, each of the CP sample data SD_C1˜SD_Cn records a first product data and a second product data. The first product data corresponds to the first product (such as an ADC circuit). The second product data corresponds to the second product (such as a DAC circuit).

In other embodiments, the prediction device 200 further comprises an input-output interface 230. The input-output interface 230 receives the training data DTR and provides the training data DTR to the processing circuit 210. In one embodiment, the WAT sample data SD_W1˜SD_Wn is provided by the wafer foundry. In this case, when the wafer foundry provides each batch of wafers to the back-end testing manufacturer, it also provides the WAT test data of the batch of wafers. In this embodiment, the WAT sample data SD_W1˜SD_Wn are WAT test data of different batches of wafers. The back-end testing manufacturer performs the CP test on different batches of wafers to generate the CP sample data SD_C1˜SD_Cn.

During a prediction period, the processing circuit 210 provides the input data DIN to the trained machine learning model ML. The trained machine learning model ML predicts the yield YL of a batch of wafers according to the correlation CORR and the input data DIN. In this embodiment, the input data DIN includes the WAT measurement data SD_M. The WAT measurement data SD_M is similar to the WAT sample data SD_W1˜SD_Wn, which are provided by the wafer foundry. In this case, the wafer foundry tests a batch of specific wafers to generate the WAT measurement data SD_M. The trained machine learning model ML predicts the yield YL of the specific wafer according to the correlation CORR and the WAT measurement data SD_M.

In some embodiments, the input-output interface 230 further receives the input data DIN and provides the input data DIN to the processing circuit 210. In other embodiments, the prediction device 200 further comprises an input-output interface 240 for outputting the predicted yield YL. In one embodiment, the processing circuit 210 outputs the predicted yield YL via the input/output interface 230.

In some embodiments, during the training period, the input-output interface 230 further receives a CP map SD_MP. In this case, the processing circuit 210 provides the CP map SD_MP, the WAT sample data SD_W1˜SD_Wn, and the CP sample data SD_C1˜SD_Cn to the machine learning model ML for training the machine learning model ML. During the prediction period, the machine learning model ML not only predicts the wafer yield YL but also predicts the location LOC of defective dies on each wafer. In one embodiment, the processing circuit 210 writes the prediction results (the location LOC of defective dies) generated by the machine learning model ML to the storage circuit 220.

In some embodiments, the machine learning model ML further predicts the yield of a specific product of each wafer in a batch of wafers. The specific product is a functional circuit, such as an ADC, a DAC, etc. Each die of each wafer has at least one functional circuit. In this case, the machine learning model ML further predicts the yield of the at least one functional circuit of each die.

Prediction methods, or certain aspects or portions thereof, may take the form of a program code (i.e., executable instructions) embodied in tangible media, such as floppy diskettes, CD-ROMS, hard drives, or any other machine-readable storage medium, wherein, when the program code is loaded into and executed by a machine such as a computer, the machine thereby becomes a prediction device for practicing the methods. The methods may also be embodied in the form of a program code transmitted over some transmission medium, such as electrical wiring or cabling, through fiber optics, or via any other form of transmission, wherein, when the program code is received and loaded into and executed by a machine such as a computer, the machine becomes a prediction device for practicing the disclosed methods. When implemented on a general-purpose processor, the program code combines with the processor to provide a unique apparatus that operates analogously to application-specific logic circuits.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein. It will be understood that although the terms “first,” “second,” etc. may be used herein to describe various elements, these elements should not be limited by these terms. These terms are only used to distinguish one element from another.

While the disclosure has been described by way of example and in terms of the preferred embodiments, it should be understood that the disclosure is not limited to the disclosed embodiments. On the contrary, it is intended to cover various modifications and similar arrangements. Therefore, the scope of the appended claims should be accorded the broadest interpretation so as to encompass all such modifications and similar arrangements.

What is claimed is:

1. A prediction method for predicting the yield of a batch of wafers, comprising:
during a training period:
receiving a plurality of first wafer acceptance test (WAT) sample data of a plurality of first wafers;
performing a wafer probe (CP) test on the first wafers to generate a plurality of first CP sample data; and
inputting the plurality of first WAT sample data and the plurality of first CP sample data into a first machine learning model, wherein the first machine learning model calculates the plurality of first WAT sample data and the plurality of first CP sample data to generate a first correlation; and
during a prediction period:
inputting first WAT measurement data into a trained machine learning model, wherein the trained machine learning model predicts the yield of the batch of wafers according to the first correlation and the first WAT measurement data.

2. The prediction method as claimed in claim 1, wherein the trained machine learning model predicts the location of defective dies on each wafer in the batch of wafers according to the first correlation and the first WAT measurement data.

3. The prediction method as claimed in claim 2, wherein the plurality of first CP sample data are electrical test results of the first wafers.

4. The prediction method as claimed in claim 2, wherein the first machine learning model calculates the plurality of first WAT sample data and abnormal electrical test results of the plurality of first CP sample data to generate the first correlation.

5. The prediction method as claimed in claim 4, wherein the CP test comprises a plurality of test items, a first part of the test items corresponds to a first product, and a second part of the test items corresponds to a second product.

6. The prediction method as claimed in claim 5, wherein the trained machine learning model predicts the yields of the first and second products in the batch of wafers according to the first correlation and the first WAT measurement data.

7. The prediction method as claimed in claim 1, wherein after the first machine learning model generates the first correlation, the first machine learning model is used as the trained machine learning model.

8. The prediction method as claimed in claim 1, further comprising:
during the training period:
receiving a plurality of second WAT sample data of a plurality of second wafers;
performing the CP test for the second wafers to generate a plurality of second CP sample data; and
inputting the plurality of second WAT sample data and the plurality of second CP sample data into a second machine learning model, wherein the second machine learning model calculates the plurality of second WAT sample data and the plurality of second CP sample data to generate a second correlation; and
during the prediction period:
selecting the first machine learning model or the second machine learning model as the trained machine learning model according to process route data of the first WAT measurement data.

9. The prediction method as claimed in claim 8, wherein:
in response to the process route data of the first WAT measurement data being the same as process route data of the plurality of first WAT sample data, the first machine learning model is selected as the trained machine learning model, and
in response to the process route data of the first WAT measurement data being the same as process route data of the plurality of second WAT sample data, the second machine learning model is selected as the trained machine learning model.

10. The prediction method as claimed in claim 8, further comprising:
during the training period:
inputting a first CP map into the first machine learning model; and
inputting a second CP map into the second machine learning model,
wherein:
the first machine learning model generates the first correlation according to the plurality of first WAT sample data, the plurality of first CP sample data, and the first CP map,
the second machine learning model generates the second correlation according to the plurality of second WAT sample data, the plurality of second CP sample data, and the second CP map,
in response to the first machine learning model being selected as the trained machine learning model, the first machine learning model predicts the location of defective dies in the batch of wafers according to the first correlation and the first WAT measurement data, and
in response to the second machine learning model being selected as the trained machine learning model, the second machine learning model predicts the location of the defective dies in the batch of wafers according to the second correlation and the second WAT measurement data.

11. A prediction device for predicting the yield of a batch of wafers, comprising:
a storage circuit storing a first machine learning model;
an input-output interface configured to receive a plurality of first WAT sample data and a plurality of first CP sample data; and
a processing circuit accessing the storage circuit to read the first machine learning model,
wherein:
during a training period:
the processing circuit provides the plurality of first WAT sample data and the plurality of first CP sample data to the first machine learning model, and
the first machine learning model calculates the plurality of first WAT sample data and the plurality of first CP sample data to generate a first correlation, and
during a prediction period:
the input-output interface receives first WAT measurement data,
the processing circuit inputs the first WAT measurement data into a trained machine learning model, and
the trained machine learning model predicts the yield of the batch of wafers according to the first correlation and the first WAT measurement data.

12. The prediction device as claimed in claim 11, wherein the trained machine learning model predicts the location of defective dies of each wafer in the batch of wafers according to the first correlation and the first WAT measurement data to generate a prediction result, and the processing circuit writes the prediction result into the storage circuit.

13. The prediction device as claimed in claim 11, wherein the trained machine learning model predicts the yield of a product in the batch of wafers according to the first correlation and the first WAT measurement data, each of the first CP sample data comprises a plurality of test results, and at least one of the test results is for the product.

14. The prediction device as claimed in claim 11, wherein the first machine learning model is used as the trained machine learning model.

15. The prediction device as claimed in claim 14, wherein after the first machine learning model generates the first correlation, the processing circuit uses the first machine learning model as the trained machine learning model and stores the trained machine learning model in the storage circuit to replace the first machine learning model.

16. The prediction device as claimed in claim 11, wherein:
during the training period:
the processing circuit provides a plurality of second WAT sample data and a plurality of second CP sample data to a second machine learning model, and
the second machine learning model calculates the plurality of second WAT sample data and the plurality of second CP sample data to generate a second correlation, and
during the prediction period:
the processing circuit uses the first machine learning model or the second machine learning model as the trained machine learning model.

17. The prediction device as claimed in claim 16, wherein the processing circuit uses the first machine learning model or the second machine learning model as the trained machine learning model according to process route data of the first WAT measurement data.

18. The prediction device as claimed in claim 17, wherein:
in response to the process route data of the first WAT measurement data being the same as process route data of the plurality of first WAT sample data, the processing circuit uses the first machine learning model as the trained machine learning model, and
in response to the process route data of the first WAT measurement data being the same as process route data of the plurality of second WAT sample data, the processing circuit uses the second machine learning model as the trained machine learning model.

19. The prediction device as claimed in claim 18, wherein:
during the training period, the processing circuit inputs a first CP map into the first machine learning model and inputs a second CP map into the second machine learning model,
the first machine learning model generates the first correlation according to the plurality of first WAT sample data, the plurality of first CP sample data, and the first CP map,
the second machine learning model generates the second correlation according to the plurality of second WAT sample data, the plurality of second CP sample data, and the second CP map,
in response to the first machine learning model being selected as the trained machine learning model, the first machine learning model predicts the location of defective dies in the batch of wafers according to the first correlation and the first WAT measurement data, and
in response to the second machine learning model being selected as the trained machine learning model, the second machine learning model predicts the location of the defective dies in the batch of wafers according to the second correlation and the second WAT measurement data.

20. A computer readable media storing a program code, wherein in response to the program code being executed, the program code accomplishes steps comprising:
during a training period:
receiving a plurality of WAT sample data of a plurality of wafers;
performing a CP test for the wafers to generate a plurality of CP sample data; and
inputting the plurality of WAT sample data and the plurality of CP sample data into a machine learning model, wherein the machine learning model calculates the plurality of WAT sample data and the plurality of CP sample data to generate a correlation; and
during a prediction period:
inputting WAT measurement data into the machine learning model, wherein the machine learning model predicts the yield of the batch of wafers according to the correlation and the WAT measurement data.
